(19) United States
(12) Patent Application Publication
(10) Pub. No.: US 2024/0402242 A1
(43) Pub. Date: Dec. 5, 2024

(54) ADJUSTABLE TEST ADAPTER APPARATUS AND SYSTEM FOR MULTIPLE QFN DEVICE TESTING

(71) Applicant: Texas Instruments Incorporated, Dallas, TX (US)

(72) Inventors: Ian Samuel Vibar, Pampanga (PH); John Lord Patawaran, Pampanga (PH); Lhord Padua, Pampanga (PH); Loven Cardenas, Mandaluyong City (PH)

(21) Appl. No.: 18/326,135

(22) Filed: May 31, 2023

(51) Int. Cl. G01R 31/28

(52) U.S. Cl. CPC G01R 31/2886

(57) ABSTRACT

A test apparatus includes a body, sliders and a clamp, where the body has an opening, first and second sliders have respective ends that face one another in the opening with positions of the first and second sliders adjustable along a first direction, third and fourth sliders have respective ends that face one another in the opening with positions of the third and fourth sliders adjustable along an orthogonal second direction, and the clamp is configured to apply a clamping force along a third direction to a device under test (DUT) positioned between the ends of the sliders, the third direction orthogonal to the first and second directions.

### BACKGROUND

Actuators can aid in performing hand socket testing during production isolation and engineering data analysis to validate integrity of an electronic device, for example, in initial unit testing. The actuators are designed for a given device package size and form factor to allow insertion and electrical connection to a circuit board of a test system. However, evaluation and testing of different sizes and forms of electronic devices requires different adaptors. Limited actuator availability per package leads to prolonged downtime and delays in lot analysis disposition due to availability an actuator as it is dedicated by package, and creating extra adapters increases costs.

### SUMMARY

In one aspect, a test apparatus includes, a body, sliders and a clamp. The body has an opening, first and second sliders have respective ends that face one another in the opening with positions of the first and second sliders adjustable along a first direction. Third and fourth sliders have respective ends that face one another in the opening with positions of the third and fourth sliders adjustable along an orthogonal second direction, and the clamp is configured to apply a clamping force along a third direction to a device under test (DUT) positioned between the ends of the sliders, the third direction orthogonal to the first and second directions.

In another aspect, a system for evaluating an electronic DUT includes a circuit board and a test apparatus. The test apparatus includes a body mounted to the circuit board and having an opening over a portion of the circuit board, as well as first and second sliders with respective ends that face one another in the opening, positions of the first and second sliders adjustable along a first direction. third and fourth sliders with respective ends that face one another in the opening, positions of the third and fourth sliders adjustable along a second direction that is orthogonal to the first direction, and a clamp configured to apply a clamping force along a third direction to engage the DUT to the portion of the circuit board between the ends of the sliders, the third direction orthogonal to the first and second directions.

In a further aspect, a method for testing an electronic DUT includes: adjusting respective positions of first and second sliders along a first direction in an opening of an adapter body mounted to a circuit board, the first and second sliders having respective ends that face one another in the opening; adjusting respective positions of third and fourth sliders along an orthogonal second direction in the opening, the third and fourth sliders having respective ends that face one another in the opening; positioning a device under test (DUT) between the ends of the sliders; engaging a clamp to apply a clamping force along a third direction to engage the DUT to a portion of the circuit board between the ends of the sliders, the third direction orthogonal to the first and second directions; and electrically testing the DUT while the DUT is engaged to the portion of the circuit board.

### BRIEF DESCRIPTION OF THE DRAWINGS

FIG. 1 is a top perspective view of a system with an adjustable test apparatus with an adapter base mounted to a circuit board for evaluating electronic devices of different sizes.

FIG. 1A is a top plan view of the adapter base with an opening and four sliders of the adjustable test apparatus of FIG. 1.

FIG. 1B is a top perspective view of a slider assembly in the test apparatus of FIGS. 1 and 1A.

FIG. 1C is a partial side elevation view of two sliders with ends that face one another in the test apparatus of FIGS. 1-1B.

FIG. 1D is a partial top view showing further details of a grooved locking feature in a slider assembly in the test apparatus of FIGS. 1-1C.

FIG. 1E is a top perspective view of an example slider body in the test apparatus of FIGS. 1-1D.

FIG. 1F is a top perspective view of an example slider spring in the test apparatus of FIGS. 1-1D.

FIG. 2 is a flow diagram of an example method of evaluating an electronic device.

FIGS. 3-6 are top plan views of the test apparatus of FIGS. 1-1D adjusted for testing four respective different quad flat no lead (QFN) electronic device size examples.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about.” “approximately.” or “substantially” preceding a value means +/−10 percent of the stated value. Modifications are possible in the described examples, and other implementations are possible, within the scope of the claims.

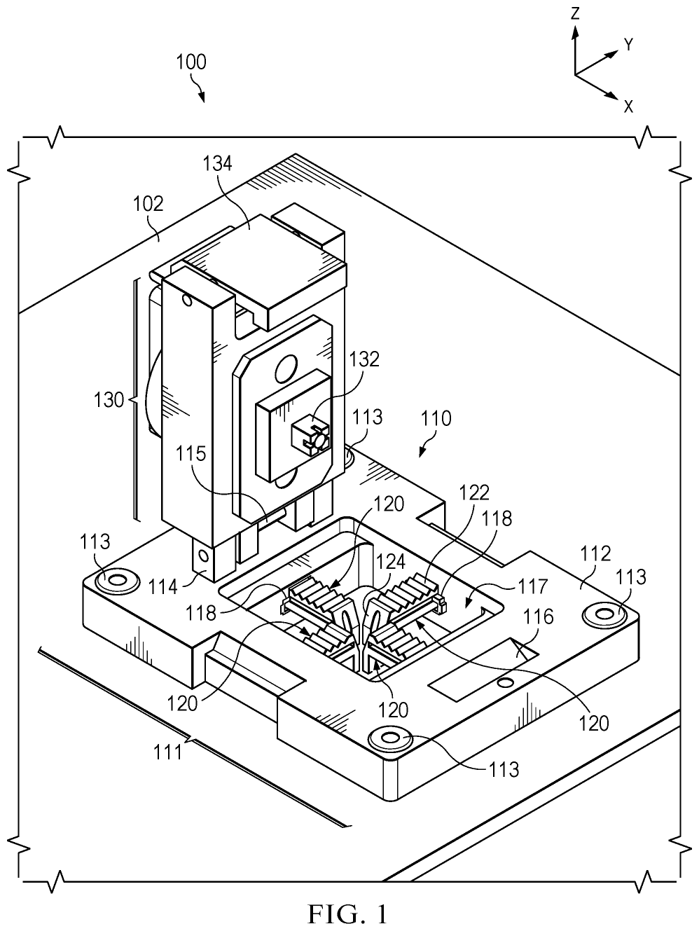

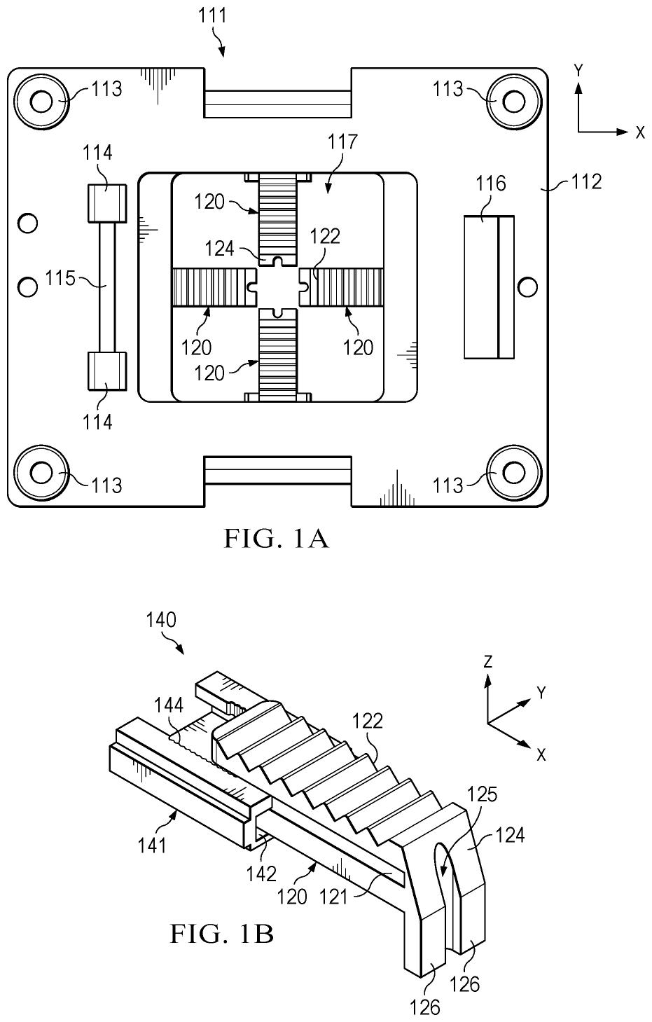

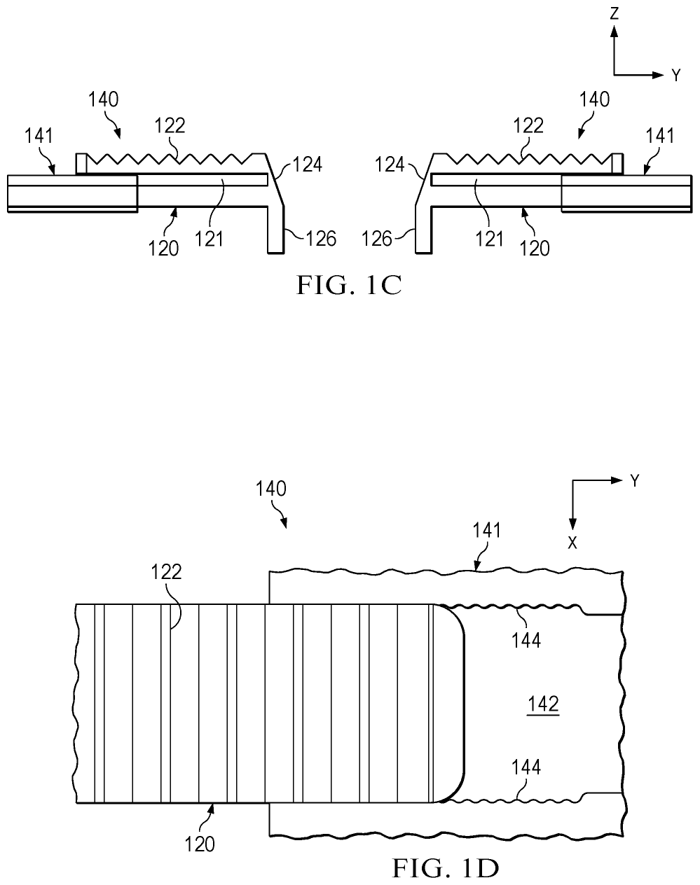

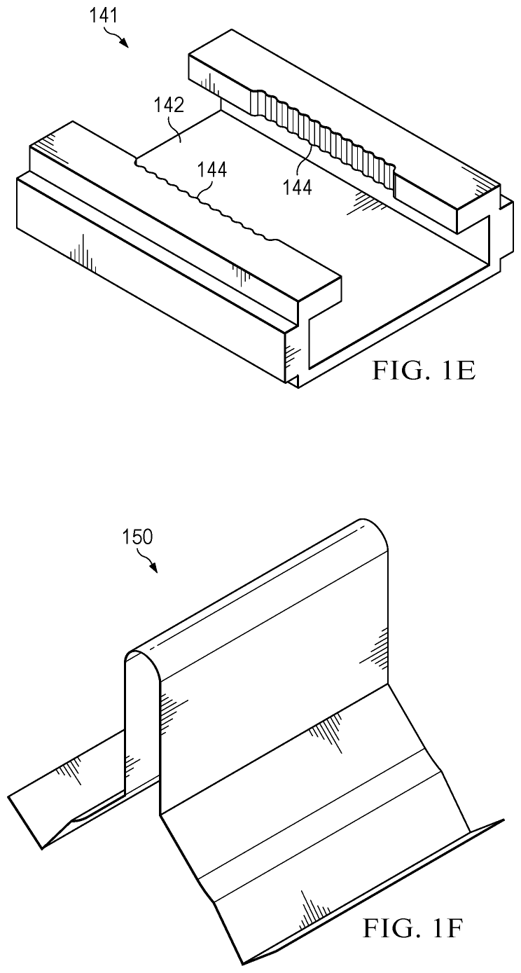

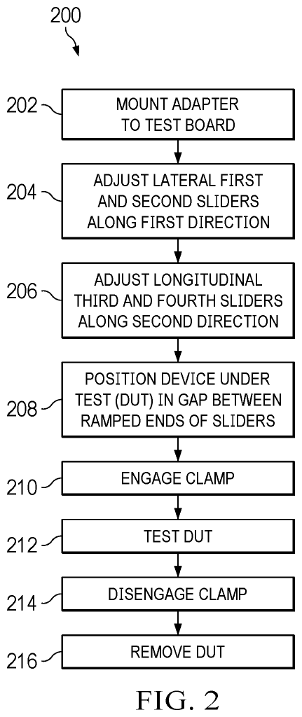

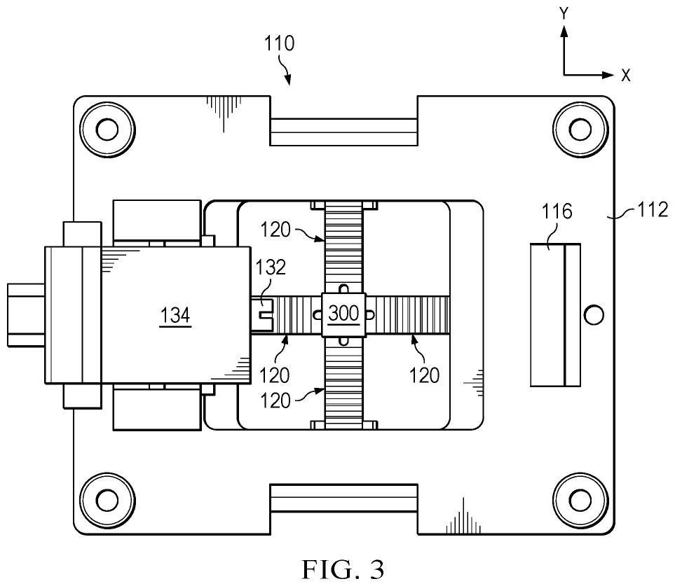

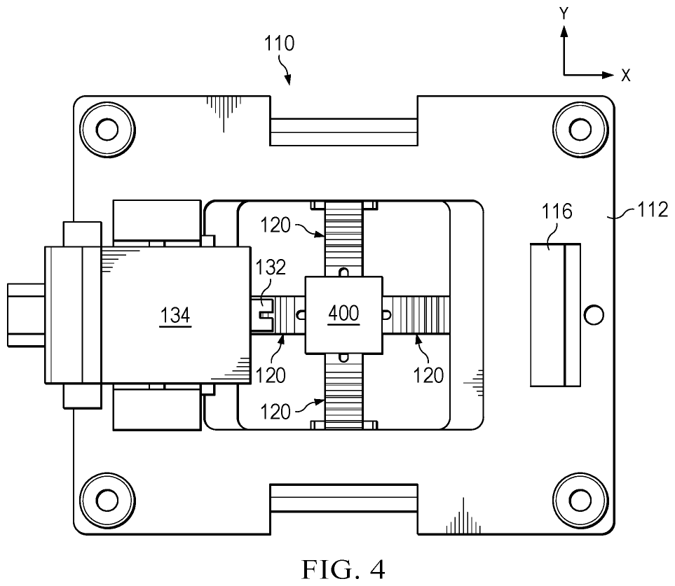

FIGS. 1-1F show an example adjustable test apparatus, also referred to as an adapter that facilitates testing or other evaluation of packaged electronic devices. FIG. 1 shows a system 100 with a circuit board 102 and a test apparatus 110. The test apparatus 110 has a body 111 mounted to a top side of the circuit board 102 as shown in FIG. 1. As shown in FIGS. 1 and 1A, the body 111 includes an adapter base 112 with holes 113 to allow screws or other fasteners (not shown) to attach the body 111 to the circuit board 102 with annular standoffs setting a non-zero gap between the bottom side of the adapter base 112 and the top side of the circuit board 102. The body 111 includes mounting tabs 114 with holes to pivotally support a clamp apparatus using a pivot pin 115, and the top side of the base 112 has a ramped slot 116 to engage a clamp tab to releasably hold the clamp apparatus in an engaged or closed position.

As further shown in FIGS. 1 and 1A, the adapter base 112 of the body 111 has an opening 117 over a portion of the circuit board 102. The body 111 is positioned with the opening 117 exposing conductive pads (not shown) of the circuit board 102, for example, arranged in a QFN or other pattern matching conductive leads of an electronic device under test, and the test apparatus provides a solution to evaluate (e.g., electrically test) a DUT installed in the test apparatus and electrically connected to test circuitry of the circuit board 102. The test apparatus allows insertion, evaluation, and removal of multiple DUTs, for example, to evaluate production electronic devices, prototypes, etc. In addition, the test apparatus is adjustable to allow installation of the body 111 with the opening 117 exposing different portions of the circuit board 102, for example, with different exposed circuit board portions having conductive pads corresponding to lead patterns of different sized DUTs, for example, QFN lead patterns for different size and form factor QFN DUTs. This allows a single test apparatus and test circuit board 102 to be used for a variety of different sizes, shapes, and configurations of DUTs.

The example opening 117 has a generally rectangular shape, although not a requirement of all possible implementations. The test apparatus is illustrated in FIGS. 1-1D in an example position or orientation in a three-dimensional space with a first direction X, an orthogonal (e.g., perpendicular) second direction Y, and a third direction Z that is orthogonal (e.g., perpendicular) to the respective first and second directions X and Y, and structures or features along any two of these directions are orthogonal to one another. As best shown in FIGS. 1 and 1A, the base 112 has a generally rectangular shape with laterally opposite sides spaced apart from one another along the first direction X, and opposite longitudinal sides spaced apart from one another along the second direction Y in the illustrated orientation, and the opening 117 extends between top and bottom sides of the base 112 generally along the third direction Z. The sides of the adapter base 112 in one example have substantially planar outer surfaces. In other examples, one or more of the adapter base sides have curves, angled features, or other non-planar surface features.

As shown in FIG. 1, the adapter base 112 of the body 111 has four body slots 118 that extend to the opening 117 along respective ones of the four internal sides of the opening 117. The test apparatus includes first and second sliders 120 that are installed in respective ones of the body slots 118 along lateral sides of the adapter base 112. The first and second sliders 120 each have ends that face one another along the first direction X in the opening 117. The respective positions of the first and second sliders 120 and the ends thereof are adjustable along the first direction X. The test apparatus also has third and fourth sliders 120 in respective body slots 118 along longitudinal sides of the adapter base 112. The third and fourth sliders 120 have respective ends that face one another along the second direction Y in the opening 117. The positions of the third and fourth sliders 120 and the ends thereof are adjustable along the second direction Y. As best shown in FIGS. 1B and 1C, the lateral sides of the individual sliders 120 have indented slider slots 121 that extend into the slider 120 along the respective one of the first and second directions X and Y.

As best shown in FIGS. 1-1D, the top sides of the respective sliders 120 have a ribbed surface 122 that allows a user to grip the sliders 120 and adjust the position of the slider 120 along the respective one of the first and second directions X and Y. The ends of the respective sliders 120 have a ramp surface 124 at a non-zero angle to the third direction Z. As best shown in FIG. 1B, the ends of the respective sliders 120 include a vertical indent 125 (FIG. 1B) that separates the end into two portions, although not a requirement of all possible implementations. In the illustrated example, the ends of the respective sliders 120 also have a second surface 126 that extends from the respective ramp surface 124 approximately along the third direction Z in the illustrated orientation.

The test apparatus includes a clamp 130 that is configured to apply a clamping force along the third direction Z to engage a DUT to a portion of the circuit board 102 between the ends of the sliders 120. Any suitable clamp can be used, where the example in FIG. 1 is pivotally mounted to rotate about the axis of the pivot pin 115. The example clamp 130 includes a pusher structure 132 having a generally rectangular shape with extended contact features at the corners of the rectangle to engage the top side of a DUT and apply the clamping force to the DUT. The clamp 130 in this example also includes a clamp tab 134 to engage the ramped slot 116 of the adapter base 112 upon downward rotation and closure of the clamp 130. The clamp tab 134 in one example is connected to or includes a release feature that allows a user to selectively displace the holding surface of the clamp tab 134 to release the clamp 130, for example, after evaluation or other testing of a DUT.

As best shown in FIGS. 1B-1E, the respective sliders 120 are included in a corresponding slider assembly 140 with a slider body 141. The slider body 141 includes a generally rectangular channel 142 laterally enclosed by sidewalls that extend along a respective one of the first and second directions X and Y. The sidewalls of the slider body 141 include an inwardly extending lip. As best shown in FIG. 1B, the lip of the slider body sidewall engages a corresponding one of the indented slider slots 121 of the slider 120. As best shown in FIGS. 1B, 1D and 1E, the lips of the slider body sidewalls include a grooved locking feature 144 that engages with corresponding grooved features of the slider 120 (not shown). The grooved locking feature 144 allows the user to incrementally adjust the position of the slider 120 within the slider body 141 along the respective one of the first and second directions X and Y to a releasably locked position desired to accommodate a given electronic device DUT. In one example, the grooved pitch of the grooved locking feature 144 is in the range of 0.1 mm to 1.0 mm to accommodate multiple different QFN package sizes and shapes for testing using the adjustable universal test apparatus. The grooved locking feature 144 operates to releasably lock the position of the slider 120 along the respective one of the first and second directions X and Y.

The example test apparatus further includes a slider spring 150 as shown in FIG. 1F that is to be paired with slider 120 to engage with both sides of the groove locking features 144 in FIG. 1E for both adjustments at 204 and 206. In its application and using FIG. 1D as a reference, the slider spring 150 moves back and forth in the X direction when the slider 120 is positioned to accommodate the X-direction dimensions of the DUT. Having adjusted the slider, a force is applied by the slider spring 150 on the trough of the groove locking features 144 to lock the slider mechanism in the desired position while also producing a clicking sound to serve as a movement indicator to a user. The slider spring 150 is also intended to be pushed back by the crest of the groove locking features 144 to unlock itself when adjustments are being made to provide releasable locking operation. In one example, the force produced by the slider spring 150 is also designed to resist the crest to automatically bring the slider 120 to the nearest trough of the groove locking features 144 to lock itself at or near an incremental position along the adjustment direction.

In operation, with the test apparatus installed on the circuit board 102 of FIG. 1, a user grasps the ribbed surface 122 of the sliders 120 and selectively adjusts the positions of the individual sliders 120 along the respective one of the first and second directions X and Y in order to set the position of the slider end at the appropriate location relative to the conductive pads (not shown) of the circuit board 102, based on the size of the DUT to be evaluated. With the sliders appropriately adjusted, and releasably locked in place by the grooved locking features 144, a DUT is positioned in the gap between the slider ends, for example, manually and/or by automated pick and place equipment (not shown). The clamp 130 is then engaged, for example, by manual or automated downward pivoting of the clamp 130 about the axis of the pivot pin 115 in FIG. 1. In practice, the positioned DUT will engage one or more of the ramp surface is 124 during actuation (e.g., engagement or closure) of the clamp 130, and the ramp surfaces 124 of one or more of the respective sliders 120 help to align the DUT along a respective one of the first and second directions X and Y as the clamp 130 applies a clamping force along the third direction Z. The ramp surface or surfaces 124 guide the DUT for lateral and longitudinal alignment as the pusher structure 132 (FIG. 1) engages the DUT during clamp actuation, and the second surface 126 of one or more of the slider ends guide the DUT approximately along the third direction Z as the clamp 130 applies the clamping force along the third direction Z. The positioning and height of the clamp pusher structure 132 in one example is set such that the pusher structure 132 provides a desired amount of clamping force along the third direction Z to mechanically engage and provide electrical connection of conductive features (e.g., leads or other electrical terminals) of the DUT with the corresponding conductive pads of the circuit board 102 when the clamp tab 134 is fully engaged and locked in the ramped slot 116 of the adapter base 112. The adjustable test apparatus provides a universal solution with an adapter base 112 mounted to the circuit board 102 and sliders 120 for evaluating electronic devices of different sizes.

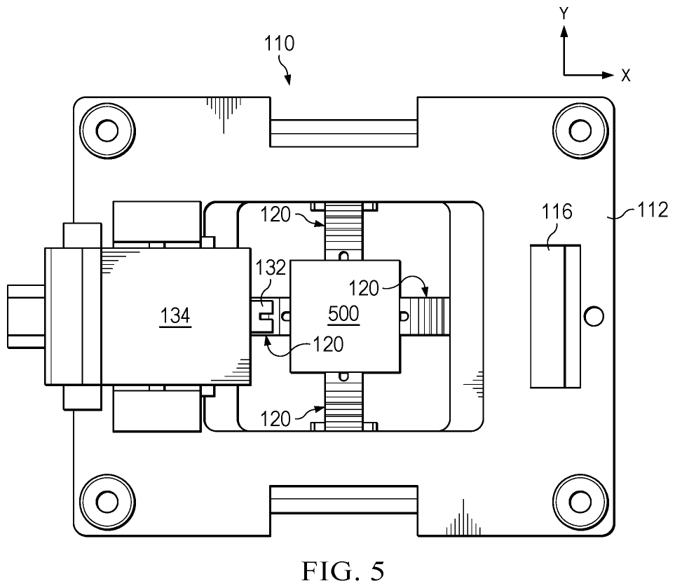

Referring also to FIGS. 2-6, FIG. 2 shows an example method 200 for evaluating an electronic device DUT and is described below in connection with the example test apparatus and system of FIGS. 1-1E. The method 200 includes mounting the adapter base 112 at 202 to a test circuit board 102, for example, using screws or other fasteners extending through the holes 113 to attach the body 111 to the circuit board 102. At 204, the method 200 includes selectively adjusting one or both of the lateral first and second sliders 120 along the first direction X. The method 200 in one example also includes longitudinal slider adjustment at 206, including selectively adjusting respective positions of the third and fourth sliders 120 along the second direction Y in the opening 117. The adjustments at 204 and/or 206 can be manual or automated or combinations thereof.

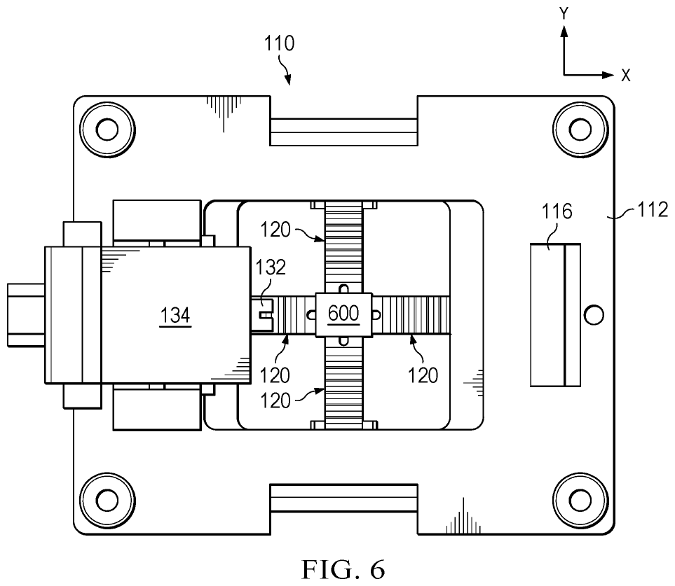

The method 200 of FIG. 2 continues at 208 with positioning 208 a DUT in the gap between the ends of the sliders 120. FIGS. 3-6 show the test apparatus of FIGS. 1-1D adjusted for testing four respective different quad flat no lead (QFN) electronic device size examples. In the example of FIG. 3, a 3 mm×3 mm QFN DUT 300 is installed in the test apparatus between the ends of the sliders 120 adjusted to the appropriate positions along the respective first and second directions X and Y. FIG. 4 shows another example implementation with a square 6 mm×6 mm QFN DUT 400 installed in the test apparatus between the ends of the sliders 120, in which the sliders 120 are positioned further away from the center of the opening 117 to accommodate the larger DUT size. In FIG. 5, and even larger square 9 mm×9 mm QFN DUT 500 is installed in the test apparatus between the ends of the sliders 120 adjusted to the appropriate positions along the respective first and second directions X and Y. FIG. 6 shows yet another example, in which a 3.5 mm×4.5 mm QFN DUT 600 is installed in the test apparatus between the ends of the sliders 120, with the sliders 120 positioned to accommodate the non-square DUT shape. The views illustrated in FIGS. 3-6 show the respective DUTs 300, 400, 500, and 600 substantially centered between the ends of the respective sliders 120, although the DUTs need not be substantially centered prior to actuation of the clamp 130.

The method 200 continues at 210 in FIG. 2 with engaging the clamp 130 to apply the clamping force along a third direction Z to engage the DUT to the portion of the circuit board 102 between the ends of the sliders 120. At 212 in FIG. 2, the method 200 continues with electrically testing or otherwise evaluating the installed and clamped DUT. At 214, the clamp is disengaged, and the evaluated DUT is removed at 216. In one implementation, for evaluating multiple DUTs of the same size, a second or subsequent DUT is then positioned in the gap between the previously adjusted sliders 120 (e.g., at 208 in FIG. 2) without having to further adjust the sliders 120, and the method 200 proceeds at 210-216 as described above for the second or subsequent DUT evaluation. If the next device to be tested is of a different size or shape, the universal test apparatus in one example is removed from the circuit board 102 and mounted to another corresponding portion of the circuit board 102 (and/or to a different test board) at 202, and suitable adjustments are selectively made to one or more of the sliders 120 at 204 and/or 206 to adapt the adjustable test apparatus to the size and shape of the next DUT to be evaluated.

The described test systems, apparatus, and methods advantageously provide a universal solution to mitigate or avoid the cost associated with maintaining an inventory of multiple adapters to accommodate testing of different device sizes and shapes, and having a relatively small number of universal adjustable adapters and test apparatus can mitigate downtime and production applications for device testing, as well as delays in evaluating prototypes or initial device designs. In one example, the test apparatus is designed for use with QFN type electronic devices to be tested or otherwise evaluated. In other implementations, different device package types, sizes, shapes and/or form factors can be accommodated by a universal adjustable adapter or test apparatus.

The above examples are merely illustrative of several possible implementations of various aspects of the present disclosure, wherein equivalent alterations and/or modifications will occur to others skilled in the art upon reading and understanding this specification and the annexed drawings.

What is claimed is:

1. A test apparatus, comprising:
a body having an opening;
first and second sliders with respective ends that face one another in the opening, positions of the first and second sliders adjustable along a first direction;
third and fourth sliders with respective ends that face one another in the opening, positions of the third and fourth sliders adjustable along a second direction that is orthogonal to the first direction; and
a clamp configured to apply a clamping force along a third direction to a device under test (DUT) positioned between the ends of the sliders, the third direction orthogonal to the first and second directions.

2. The test apparatus of claim 1, wherein the ends of the respective sliders have a ramp surface at a non-zero angle to the third direction to align the DUT along a respective one of the first and second directions as the clamp applies the clamping force along the third direction.

3. The test apparatus of claim 2, wherein the ends of the respective sliders have a second surface extending from the ramp surface to guide the DUT approximately along the third direction as the clamp applies the clamping force along the third direction.

4. The test apparatus of claim 2, wherein the respective sliders have a ribbed surface to allow a user to grip the slider and adjust the position of the slider along the respective one of the first and second directions.

5. The test apparatus of claim 2, wherein the respective sliders have a grooved locking feature to releasably lock the position of the slider along the respective one of the first and second directions.

6. The test apparatus of claim 1, wherein the respective sliders have a ribbed surface to allow a user to grip the slider and adjust the position of the slider along the respective one of the first and second directions.

7. The test apparatus of claim 6, wherein the respective sliders have a grooved locking feature to releasably lock the position of the slider along the respective one of the first and second directions.

8. The test apparatus of claim 1, wherein the respective sliders have a grooved locking feature to releasably lock the position of the slider along the respective one of the first and second directions.

9. A system for evaluating an electronic device under test (DUT), comprising:
a circuit board; and
a test apparatus, comprising:
a body mounted to the circuit board and having an opening over a portion of the circuit board;
first and second sliders with respective ends that face one another in the opening, positions of the first and second sliders adjustable along a first direction;
third and fourth sliders with respective ends that face one another in the opening, positions of the third and fourth sliders adjustable along a second direction that is orthogonal to the first direction; and
a clamp configured to apply a clamping force along a third direction to engage the DUT to the portion of the circuit board between the ends of the sliders, the third direction orthogonal to the first and second directions.

10. The system of claim 9, wherein the ends of the respective sliders have a ramp surface at a non-zero angle to the third direction to align the DUT along a respective one of the first and second directions as the clamp applies the clamping force along the third direction.

11. The system of claim 10, wherein the ends of the respective sliders have a second surface extending from the ramp surface to guide the DUT approximately along the third direction as the clamp applies the clamping force along the third direction.

12. The system of claim 9, wherein the respective sliders have a ribbed surface to allow a user to grip the slider and adjust the position of the slider along the respective one of the first and second directions.

13. The system of claim 12, wherein the respective sliders have a grooved locking feature to releasably lock the position of the slider along the respective one of the first and second directions.

14. The system of claim 9, wherein the respective sliders have a grooved locking feature to releasably lock the position of the slider along the respective one of the first and second directions.

15. A method for testing an electronic device under test (DUT), the method comprising:
adjusting respective positions of first and second sliders along a first direction in an opening of an adapter body mounted to a circuit board, the first and second sliders having respective ends that face one another in the opening;
adjusting respective positions of third and fourth sliders along an orthogonal second direction in the opening, the third and fourth sliders having respective ends that face one another in the opening;
positioning a device under test (DUT) between the ends of the sliders;
engaging a clamp to apply a clamping force along a third direction to engage the DUT to a portion of the circuit board between the ends of the sliders, the third direction orthogonal to the first and second directions; and
electrically testing the DUT while the DUT is engaged to the portion of the circuit board.

16. The method of claim 15, wherein:
the ends of the respective sliders have a ramp surface at a non-zero angle to the third direction; and
engaging the clamp includes the ramp surface aligning the DUT along a respective one of the first and second directions as the clamp applies the clamping force along the third direction.

17. The method of claim 16, wherein:
the ends of the respective sliders have a second surface extending from the ramp surface; and
engaging the clamp includes the second surface guiding the DUT approximately along the third direction as the clamp applies the clamping force along the third direction.

18. The method of claim 16, wherein:
the respective sliders have a grooved locking feature;
adjusting the respective positions of the first and second sliders includes locking the positions of the first and second sliders along the first direction; and
adjusting the respective positions of the third and fourth sliders includes locking the positions of the second and third sliders along the second direction.

19. The method of claim 15, wherein:
the ends of the respective sliders have a surface; and
engaging the clamp includes the surface guiding the DUT approximately along the third direction as the clamp applies the clamping force along the third direction.

20. The method of claim 15, wherein:
the respective sliders have a grooved locking feature;
adjusting the respective positions of the first and second sliders includes locking the positions of the first and second sliders along the first direction; and
adjusting the respective positions of the third and fourth sliders includes locking the positions of the second and third sliders along the second direction.
